(19) United States
(12) Patent Application Publication
(10) Pub. No.: US 2012/0153264 A1
(43) Pub. Date: Jun. 21, 2012

(54) Methods For Forming Organic Thin Film, Organic Thin Films, Thin Film Transistors Including The Same, And Electric Devices Including The Same

(75) Inventors: Jong-Jin Park, Hwaseong-si (KR); Kyu Hyun Im, Yongin-si (KR); Chan-Eon Park, Pohang-si (KR); Jong Min Kim, Yongin-si (KR); Jin Eun Kim, Gwangju-si (KR)

(73) Assignee: SAMSUNG ELECTRONICS CO., LTD., Suwon-si (KR)

(21) Appl. No.: 13/099,758

(22) Filed: May 3, 2011

(30) Foreign Application Priority Data
Dec. 15, 2010 (KR) 10-2010-0128288

(51) Int. Cl. H01L 51/10; B32B 5/12; B05D 5/12

(52) U.S. Cl. 257/40; 427/58; 428/114; 257/E51.005

(57) ABSTRACT

A method of forming an organic thin film may include providing a substrate; providing an organic solution including an organic solute and a solvent having a boiling point of about 85° C. or less; dipping the substrate into the organic solution; removing the substrate from the organic solution; and/or precipitating the organic solute on the substrate to provide an organic thin film, wherein the removing the substrate from the organic solution is performed at a speed of about 10 to about 300 μm/s from one end of the substrate to the other end of the substrate. Accordingly, an organic thin film having advantageous characteristics and a wide area may be obtained.

### CROSS-REFERENCE TO RELATED APPLICATION

This application claims priority under 35 U.S.C. §119 to Korean Patent Application No. 10-2010-0128288, filed in the Korean Intellectual Property Office on Dec. 15, 2010, the entire contents of which are incorporated herein by reference.

### BACKGROUND

1. Field

Example embodiments relate to methods of forming an organic thin film, organic thin films, thin film transistors, and electronic devices including the same.

2. Description of the Related Art

An organic material may be applied to various fields, including organic light emitting devices, organic semiconductors, and other related technologies.

For example, an organic material may be applied to a flexible display, because the organic material itself is flexible. In addition, the organic material may be fabricated at a lower cost and with a simpler process.

The organic material may be classified as a crystalline material or a non-crystalline material. Generally, the crystalline material may have higher mobility as the crystallinity of the material increases.

In order to provide a layer having higher mobility, it may be beneficial to take the method of forming the layer as well as the characteristics of the organic material into account.

The organic material may be generally formed as a thin layer on a substrate. The layer forming method may include spin coating, drop casting, or other suitable techniques.

In the case of using spin coating, the solvent may evaporate too quickly for a solute to provide a uniform layer. In addition, the layer may crystallize radially according to the angle speed during spinning, so it may be relatively difficult to provide a uniform layer in one direction.

Furthermore, when using a drop casting method, a solvent having a relatively high boiling point may be involved. Because of the relatively high boiling point, the solvent may evaporate relatively slowly. As a result, the overall process time may be prolonged.

### SUMMARY

Example embodiments relate to methods of forming an organic thin film having a relatively wide area.

Example embodiments additionally relate to organic thin films formed according to the methods described herein so as to have advantageous characteristics.

Example embodiments also relate to a thin film transistor including one or more of the organic thin films described herein.

Example embodiments further relate to electronic devices including one or more of the thin film transistors described herein.

A method of forming an organic thin film according to example embodiments may include providing a substrate; providing an organic solution including an organic solute and a solvent having a boiling point of about 85° C. or less; dipping the substrate into the organic solution; removing the substrate from the organic solution; and precipitating the organic solute on the substrate to provide an organic thin film, wherein the removing the substrate from the organic solution is performed at a speed of about 10 to about 300 μm/s from the one end to the other of the substrate.

The solvent may have a boiling point in a range of about 35 to about 85° C.

The solvent may include acetone, methylethylketone, chloroform, dichloromethane, tetrahydrofuran, acetonitrile, benzene, cyclohexane, dichloroethane, ethanol, ethyl acetate, petroleum ether, or a combination thereof.

While the substrate is being removed from the organic solution from one end to the other of the substrate at a speed of about 10 to 300 μm/s, the speed may be constant.

While the substrate is being removed from the organic solution from one end to the other at a speed of about 10 to 300 μm/s, the speed may be in a range of about 10 to about 150 μm/s.

The organic solute may include anthracene, tetracene, pentacene, merocyanine, copper phthalocyanine, perylene, rubrene, anthradithiophene, polyfluorene, polyacetylene, polydiacetylene, polythiophene, oligothiophene, polyisothianaphthene, polyarylenevinylene, polyaniline, polycarbazole, polyfuran, polyacene, or derivatives thereof.

The obtained organic thin film may include a plurality of crystals aligned in the form of stripes.

The organic thin film may have a carrier mobility of about 0.1 cm²/Vs or more.

The organic thin film may have a carrier mobility of about 0.5 cm²/Vs or more.

The organic solute in the organic solution may be included at about 0.1 to about 2 wt %.

The obtained organic thin film may have a thickness of about 10 nm to about 5 μm.

An organic thin film according to example embodiments may include a plurality of crystals aligned in the form of stripes such that the organic thin film has a carrier mobility of about 0.5 cm²/Vs or more.

The organic thin film may have a thickness of about 10 nm to about 5 μm.

The organic thin film may include anthracene, tetracene, pentacene, merocyanine, copper phthalocyanine, perylene, rubrene, anthradithiophene, polyfluorene, polyacetylene, polydiacetylene, polythiophene, oligothiophene, polyisothinanaphthene, polyarylenevinylene, polyaniline, polycarbozole, polyfuran, polyacene, or derivatives thereof.

The organic thin film may be formed according to the methods described herein for forming an organic thin film.

A thin film transistor according to example embodiments may include a gate electrode, a semiconductor overlapped with the gate electrode, a gate dielectric layer disposed between the gate electrode and the semiconductor, and a source electrode and a drain electrode electrically connected to the semiconductor, wherein the semiconductor may include an organic thin film.

An electronic device according to example embodiments may include one or more of the thin film transistors described herein.

As described herein, an organic thin film having advantageous characteristics and a relatively wide area may be provided. In addition, a thin film transistor and an electronic device including the organic thin film may be provided.

### BRIEF DESCRIPTION OF THE DRAWINGS

FIGS. 1 and 2 are schematic views showing a state in which a substrate is removed from an organic solution while forming an organic thin film according to example embodiments.

FIG. 3 is a surface SEM image of the organic thin film of Example 2.

FIG. 4 is a surface SEM image of the organic thin film of Example 3.

FIG. 5 is a surface SEM image of the organic thin film of Example 4.

FIG. 6 is a surface SEM image of the organic thin film of Example 8.

FIG. 7 is a surface SEM image of the organic thin film of Example 10.

FIG. 8 is a cross-sectional view of a thin film transistor according to example embodiments.

### DETAILED DESCRIPTION

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms, “comprises,” “comprising,” “includes,” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Example embodiments will hereinafter be described in further detail. However, it should be understood that these non-limiting embodiments are merely examples and are not intended to limit the scope of the present invention.

According to example embodiments, a method of forming an organic thin film may include providing a substrate; providing an organic solution including an organic solute and a solvent having a boiling point of about 85° C. or less; dipping the substrate into the organic solution; removing the substrate from the organic solution; and/or precipitating the organic solute on the substrate to provide an organic thin film, wherein the removing the substrate from the organic solution may be performed at a speed of about 10 to about 300 μm/s from one end to the other end of the substrate.

The substrate may be a flexible substrate or a non-flexible substrate. Examples of the flexible substrate may include a polyimide-based substrate, a polyether-based substrate, a polycarbonate-based substrate, an amorphous polyolefin-based substrate, an epoxy resin substrate, a polyethylene terephthalate-based substrate, a polyethersulfone substrate, a triacetyl cellulose substrate, a polyvinyl alcohol substrate, a polymethylmethacrylate substrate, and other suitable materials. Examples of the non-flexible substrate may include a glass substrate, a silicon-based substrate, and other suitable materials.

The organic solute may be a conductive material, e.g., anthracene, tetracene, pentacene, merocyanine, copper phthalocyanine, perylene, rubrene, anthradithiophene, polyfluorene, polyacetylene, polydiacetylene, polythiophene, oligothiophene, polyisothinanaphthene, polyarylenevinylene, polyaniline, polycarbozole, polyfuran, polyacene, or derivatives thereof. However, it should be understood that the conductive material is not limited to those listed above and may be selected depending upon the type of substrate and the thin film characteristics to be obtained.

The solvent may have a boiling point of about 85° C. or less at 1 atm. For instance, the boiling point may be in a range of about 35 to about 85° C. at 1 atm. Examples of the solvent may include acetone (56.3° C.), methylethylketone (79.64° C.), chloroform (62° C.), dichloromethane (40.4° C.), tetrahydrofuran (67° C.), acetonitrile (81.6° C.), benzene (80° C.), cyclohexane (80.74° C.), dichloroethane (83.48° C.), ethanol (78.3° C.), ethyl acetate (77.1° C.), petroleum ether (60° C.), or a combination thereof.

The organic solute in the organic solution may be included at about 0.1 to about 2 wt %. Such a range may be appropriate for providing an organic thin film.

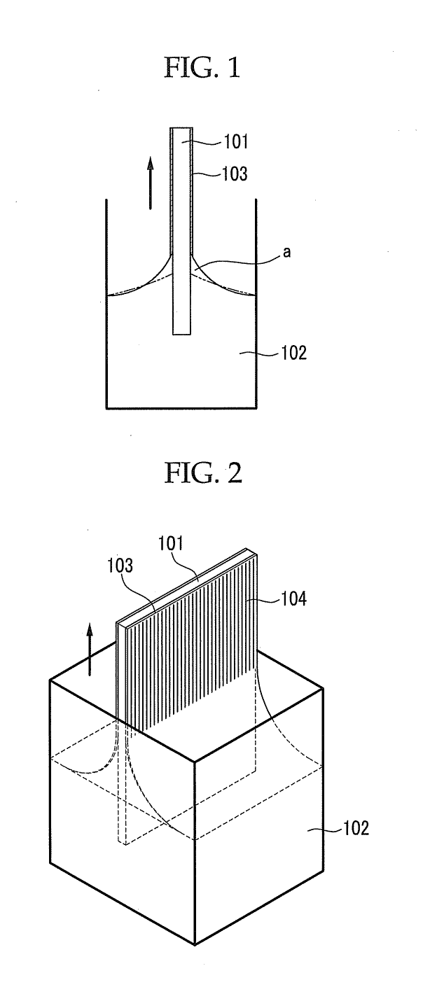

FIGS. 1 and 2 are schematic views showing a state in which a substrate is removed from an organic solution while providing an organic thin film according to example embodiments. The arrow direction of FIGS. 1 and 2 indicates a movement direction of a substrate 101.

After dipping the substrate 101 into an organic solution 102, the substrate 101 is removed from the organic solution 102 so as to result in an organic thin film 103 being formed on the substrate 101.

The substrate 101 may be removed from the organic solution 102 at a speed of about 10 to 300 μm/s based on a movement from one end of the substrate 101 to an opposing end of the substrate 101 relative to a reference point. For instance, if the substrate 101 is completely immersed in the organic solution 102, the reference point may be the planar upper surface of the organic solution 102, and the speed may be based on the time from when the top end of the substrate 101 is lifted above the planar upper surface of the organic solution 102 to when the bottom end of the substrate 101 is lifted above the planar upper surface of the organic solution 102.

The speed at which the substrate 101 is removed from the organic solution 102 may be constant.

The boiling point of the solvent and the movement speed of the substrate 101 may be adjusted depending upon the desired characteristics of the resulting organic thin film 103. For example, when the solvent has a relatively low boiling point, the solvent in the organic solution 102 on the substrate 101 may be evaporated too quickly to provide an acceptable organic thin film 103. Also, when the substrate 101 is removed too quickly, it may be difficult to draw the organic solution 102 to provide an acceptable organic thin film 103.

On the other hand, when the solvent has a relatively high boiling point, the solvent in the organic solution 102 may be difficult to evaporate, so as to draw too much organic solute. As a result, the organic thin film 103 may be thicker, and the time for forming the organic thin film 103 may be prolonged. Also, when the movement speed of the substrate 101 is relatively slow, an excessive amount of organic solution 102 may be drawn to provide an organic thin film 103 with a relatively thick thickness.

An organic thin film 103 having desirable characteristics may be provided by adjusting, for instance, the boiling point of the solvent and the movement speed of the substrate 101.

When the substrate 101 is moved along the arrow direction of FIG. 1 and FIG. 2, a part of the organic solution 102 is drawn along the movement direction of the substrate 101 by surface tension. The amount of the organic solution 102 drawn may be different depending upon the movement speed of the substrate 101 and the boiling point of the organic solution 102.

When the solvent in the organic solution 102 is evaporated, the organic solute remains on the substrate 101 to provide the organic thin film 103. The organic thin film 103 may be continuously formed during the movement of the substrate 101.

FIG. 1 shows that the organic solution 102 is drawn in the movement direction of the substrate 101 at the interface of the organic solution 102 and the substrate 101. The solid line and the two-point chain line may indicate the difference in movement speed of the substrate 101.

For instance, when the speed of removing the substrate 101 from the organic solution 102 is relatively fast, the interface may be formed as shown by the solid line. On the other hand, when the speed of removing the substrate 101 from the organic solution 102 is relatively slow, the interface may be formed as shown by the two-point chain line.

In addition, since the solvent has a relatively low boiling point of 85° C. or less, the solvent may be rapidly evaporated. The surface tension of the solute may be decreased on the substrate 101 due to the relatively fast evaporation speed. The precipitated organic thin film 103 may include a plurality of crystals 104 aligned in the form of stripes. As shown in FIG. 2, the organic thin film 103 may include a plurality of crystals 104 aligned in the form of stripes extending along the direction in which the substrate 101 is removed from the organic solution 102.

During the step of removing the substrate 101 from the organic solution 102, the speed may be in a range of about 10 to about 300 μm/s. For example, the speed may be in a range of about 10 to about 150 μm/s. In another instance, the speed may be about 50 to about 150 μm/s.

When satisfying the pertinent speed range, an organic thin film 103 having an appropriate thickness and crystallinity may be provided.

Since the organic thin film 103 includes a plurality of crystals 104 aligned in the form of stripes, the organic thin film 103 may have carrier mobility of about 0.1 cm²/Vs or more. For example, the carrier mobility may be in a range of about 0.5 cm²/Vs or more. In another instance, the carrier mobility may be about 0.8 cm²/Vs or more. In yet another instance, the carrier mobility may be about 1.0 cm²/Vs or more. As the carrier mobility of the organic thin film 103 increases, the organic thin film 103 may have more advantageous characteristics.

The organic thin film 103 may have a thickness of about 10 nm to about 5 μm. This thickness range may be beneficial when applying the organic thin film 103 to a thin film transistor or an electronic device.

According to another non-limiting embodiment, an organic thin film 103 may include a plurality of crystals 104 aligned in stripes and may have a carrier mobility of about 0.5 cm²/Vs or more.

The organic thin film 103 may have a thickness of about 10 nm to about 5 μm.

Since the organic thin film 103 includes a plurality of crystals 104 aligned in stripes, it may have beneficial characteristics in the view of its carrier mobility.

For example, the carrier mobility may be in a range of about 0.8 cm²/Vs or more, or about 1.0 cm²/Vs or more. As the carrier mobility is increased, the characteristics of the organic thin film 103 may be improved.

The organic thin film 103 may include anthracene, tetracene, pentacene, merocyanine, copper phthalocyanine, perylene, rubrene, anthradithiophene, polyfluorene, polyacetylene, polydiacetylene, polythiophene, oligothiophene, polyisothianaphthene, polyarylenevinylene, polyaniline, polycarbazole, polyfuran, polyacene, or derivatives thereof. However, it should be understood that example embodiments are not limited thereto.

The organic thin film 103 may be formed by the above-discussed method of forming an organic thin film according to example embodiments.

According to another non-limited embodiment, a thin film transistor may be provided that includes a gate electrode, a semiconductor overlapped with the gate electrode, a gate dielectric layer disposed between the gate electrode and the semiconductor, and a source electrode and a drain electrode electrically connected to the semiconductor, wherein the semiconductor includes the organic thin film.

FIG. 8 is a cross-sectional view of a thin film transistor according to example embodiments. Referring to FIG. 8, a bottom gate-structured thin film transistor is illustrated, which may be sequentially formed with a substrate 110, a gate electrode 124 formed on the substrate 110, a gate dielectric layer 140, a semiconductor 154, a source electrode 173, and a drain electrode 175.

The substrate 110 may include glass, a polymer, a silicon wafer, or other suitable materials. The gate electrode 124 may be connected to a gate line (not shown) extending along one direction of the substrate 110.

The semiconductor 154 may be formed so as to overlap with the gate electrode 124. The gate dielectric layer 140 may be formed between the gate electrode 124 and the semiconductor 154 so as to cover the entire surface of the substrate 110. The source electrode 173 and the drain electrode 175 may be formed on the semiconductor 154 so as to be electrically connected to the semiconductor 154 to enable the application of a voltage.

The semiconductor 154 may include the organic thin film 103 discussed above. The organic thin film 103 may include a plurality of crystals 104 aligned in the form of stripes so as to provide increased carrier mobility and reduced charge loss in the channel region of the thin film transistor. As a result, the characteristics of the thin film transistor may be improved.

According to a further non-limiting embodiment, an electronic device including the thin film transistor may be provided. The electronic device may include a solar cell, an organic light emitting diode, or other related device.

Using the method of forming an organic thin film according to example embodiments, a display (e.g., monitor, TV, or other related device), audio equipment (e.g., radio, MP3, or other related device), a game console, a mobile phone, or other related device may be provided. Among the processes of fabricating the electronic device, the conventional thin film forming process may be substituted with the method of forming an organic thin film according to example embodiments.

Hereinafter, example embodiments are disclosed in further detail. However, it should be understood that the following are merely examples and should not be construed as limiting the scope of the present invention.

### EXAMPLE

### Formation of Organic Thin Film

### Example 1

Triisopropylsilylethynyl pentacene (TIPS-PEN) represented by the following Chemical Formula 1 is used as an organic solute, and dichloromethane is used as a solvent. The dichloromethane is known to have a boiling point of 39.6° C.

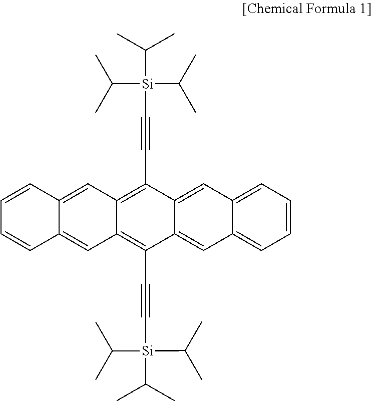

The organic solute is included at about 0.2 wt % in the organic solution, and the substrate is fabricated as a silicon substrate.

The substrate is dipped in the organic solution and removed from the organic solution at a speed of about 10 μm/s.

### Example 2

An organic thin film is fabricated in accordance with the same procedure as set forth in Example 1, except that the substrate is removed at a speed of about 50 μm/s.

### Example 3

An organic thin film is fabricated in accordance with the same procedure as set forth in Example 1, except that the substrate is removed at a speed of about 100 μm/s.

### Example 4

An organic thin film is fabricated in accordance with the same procedure as set forth in Example 1, except that the substrate is removed at a speed of about 150 μm/s.

### Example 5

An organic thin film is fabricated in accordance with the same procedure as set forth in Example 1, except that the organic solute is fluorinated triethylsilyl anthradithiophene (FTES-ADT) represented by the following Chemical Formula 2.

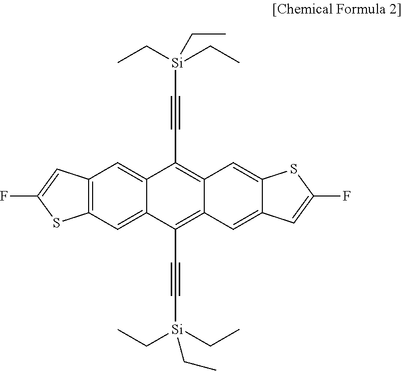

### Example 6

An organic thin film is fabricated in accordance with the same procedure as set forth in Example 5, except that the substrate is removed at a speed of about 50 μm/s.

### Example 7

An organic thin film is fabricated in accordance with the same procedure as set forth in Example 5, except that the substrate is removed at a speed of about 100 μm/s.

### Example 8

An organic thin film is fabricated in accordance with the same procedure as set forth in Example 5, except that the substrate is removed at a speed of about 150 μm/s.

### Example 9

An organic thin film is fabricated in accordance with the same procedure as set forth in Example 1, except that the solvent is chloroform. Chloroform is known to have a boiling point of about 61.2° C.

### Example 10

An organic thin film is fabricated in accordance with the same procedure as set forth in Example 9, except that the substrate is removed at a speed of about 50 μm/s.

### Example 11

An organic thin film is fabricated in accordance with the same procedure as set forth in Example 9, except that the substrate is removed at a speed of about 150 μm/s.

### Example 12

An organic thin film is fabricated in accordance with the same procedure as set forth in Example 9, except that the organic solute is fluorinated triethylsilyl anthradithiophene.

### Example 13

An organic thin film is fabricated in accordance with the same procedure as set forth in Example 12, except that the substrate is removed at a speed of about 50 μm/s.

### Comparative Example 1

An organic thin film is fabricated in accordance with the same procedure as set forth in Example 1, except that the substrate is removed at a speed of about 350 μm/s.

### Comparative Example 2

An organic thin film is fabricated in accordance with the same procedure as set forth in Example 9, except that the substrate is removed at a speed of about 350 μm/s.

### Comparative Example 3

An organic thin film is fabricated in accordance with the same procedure as set forth in Example 12, except that the substrate is removed at a speed of about 350 μm/s.

### Comparative Example 4

The material obtained from Example 1 is substituted with 0.5 wt % of a toluene solution (boiling point: 110.6° C.), and the solvent of a 3.5 degree-leaned silicon substrate is slowly natural-dried and completely evaporated in a closed glass chamber according to the drop casting method to provide an organic thin film.

### EXAMPLE

### Fabrication of Field Effect Transistor (FET)

### Example 14

A field effect transistor is fabricated so as to include the organic thin film obtained from Example 3.

A substrate of an n-type Si wafer is cleaned with a piranha solution and re-cleaned with distilled water. An aluminum gate electrode is obtained in a thickness of about 200 nm by e-beam deposition. An Al₂O₃ gate dielectric layer is formed on a substrate at a thickness of about 100 nm by atomic layer deposition. A Si wafer substrate is dipped in a 0.2 wt % semiconductor solution at a speed of about 1000 μm/s, and the substrate is removed at a speed of about, 100 μm/s. Source and drain electrodes are formed with gold on the stripe-patterned semiconductor crystal formed by thermal evaporation by using a shadow mask. Each gold electrode has a width of about 55.0 μm and an electrode gap of about 22.5 μm.

### Example 15

A field effect transistor is fabricated in accordance with the same procedure as set forth in Example 14, except that the method of preparing an organic thin film obtained from Example 4 is used instead of the method of preparing an organic thin film obtained from Example 3.

### Example 16

A field effect transistor is fabricated in accordance with the same procedure as set forth in Example 14, except that the method of preparing an organic thin film obtained from Example 6 is used instead of the method of preparing an organic thin film obtained from Example 3.

### Example 17

A field effect transistor is fabricated in accordance with the same procedure as set forth in Example 14, except that the method of preparing an organic thin film obtained from Example 11 is used instead of the method of preparing an organic thin film obtained from Example 3.

### Comparative Example 5

A field effect transistor is fabricated in accordance with the same procedure as set forth in Example 14, except that the method of preparing an organic thin film obtained from Comparative Example 1 is used instead of the method of preparing an organic thin film obtained from Example 3.

### Comparative Example 6

A field effect transistor is fabricated in accordance with the same procedure as set forth in Example 14, except that the method of preparing an organic thin film obtained from Comparative Example 2 is used instead of the method of preparing an organic thin film obtained from Example 3.

### Comparative Example 7

A field effect transistor is fabricated in accordance with the same procedure as set forth in Example 14, except that the method of preparing an organic thin film obtained from Comparative Example 3 is used instead of the method of preparing an organic thin film obtained from Example 3.

### Comparative Example 8

A field effect transistor is fabricated in accordance with the same procedure as set forth in Example 14, except that the method of preparing an organic thin film obtained from Comparative Example 4 is used instead of the method of preparing an organic thin film obtained from Example 3.

### EXPERIMENTAL EXAMPLE

### Confirmation of Obtained Organic Thin Film

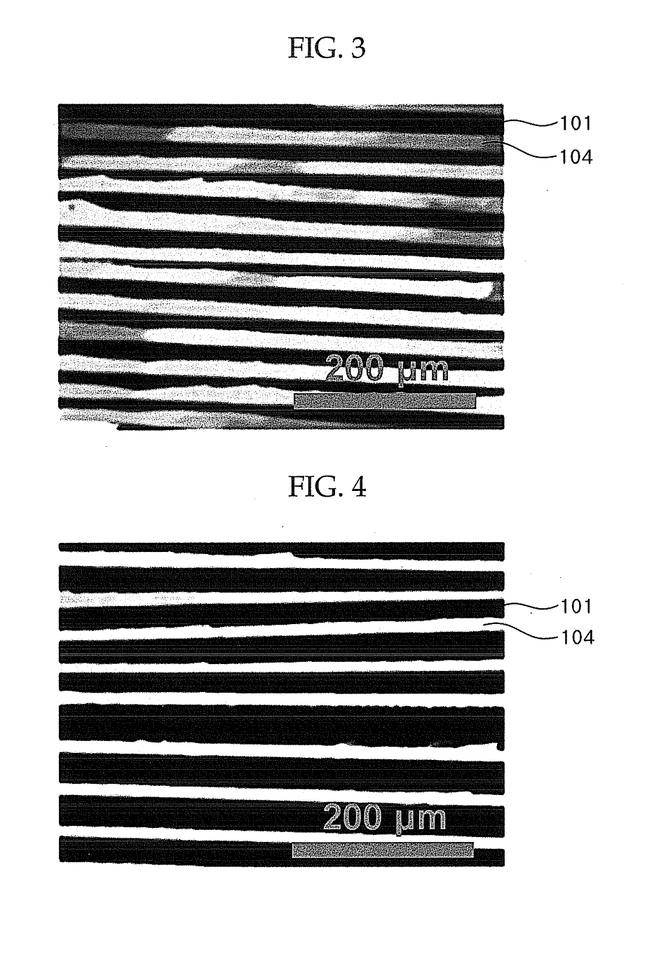

FIG. 3 is a photograph of the organic thin film obtained from Example 2 and shows that the organic thin film includes a plurality of crystals 104 aligned in the form of stripes on the substrate 101.

FIG. 4 is a photograph of the organic thin film obtained from Example 3 and shows that the organic thin film includes a plurality of crystals 104 aligned in the form of stripes on the substrate 101.

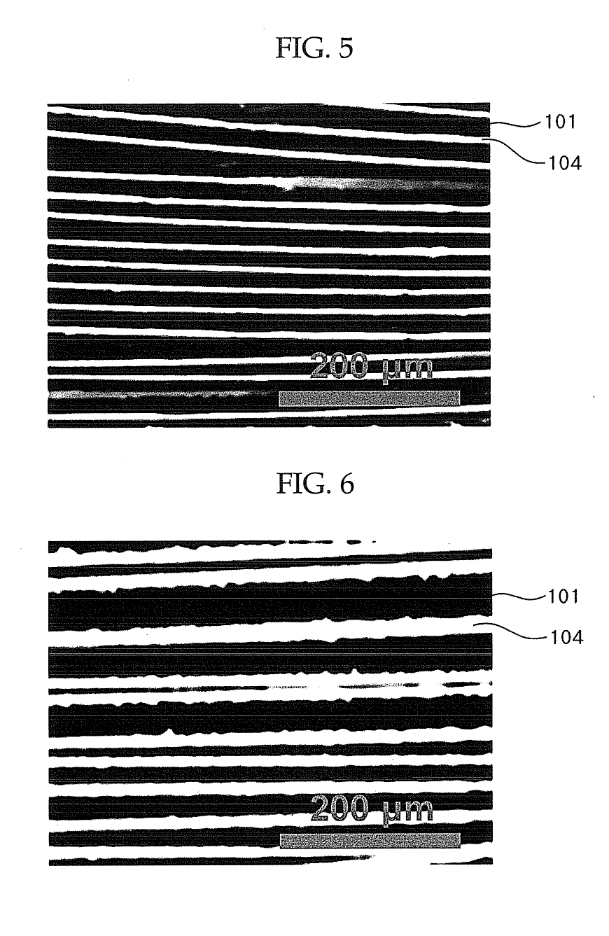

FIG. 5 is a photograph of the organic thin film obtained from Example 4 and shows that the organic thin film includes a plurality of crystals 104 aligned in the form of stripes on the substrate 101.

FIG. 6 is a photograph of the organic thin film obtained from Example 8 and shows that the organic thin film includes a plurality of crystals 104 aligned in the form of stripes on the substrate 101.

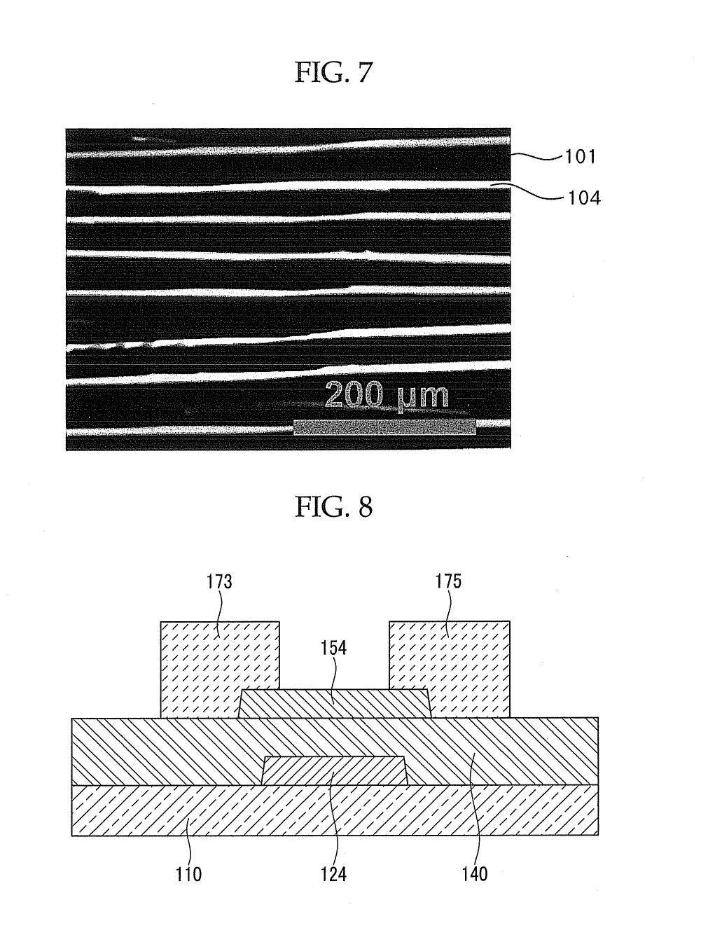

FIG. 7 is a photograph of the organic thin film obtained from Example 10 and shows that the organic thin film includes a plurality of crystals 104 aligned in the form of stripes on the substrate 101.

In FIGS. 3 to 7, the region shown as not being covered by the plurality of crystals 104 aligned in stripes is the substrate 101.

TABLE 1

| | Mobility | on/off |
|---|---|---|
| | (μ, cm²/Vs) | ratio |
| Example 14 | 1.0 | 1.6 × 10⁶ |
| Example 15 | 1.5 | 9.3 × 10⁵ |
| Example 16 | 1.5 | 7.64 × 10⁵ |
| Example 17 | 1.5 | 7.05 × 10⁵ |
| Comparative | 0.2 | 5.45 × 10⁴ |
| Example 5 | | |
| Comparative | 0.2 | 6.37 × 10⁴ |
| Example 6 | | |
| Comparative | 0.2 | 3.21 × 10⁴ |
| Example 7 | | |
| Comparative | 0.4 | 1.7 × 10⁶ |
| Example 8 | | |

As shown in Table 1, the field effect transistors according to Examples 14 to 17 have better characteristics such as mobility and on/off ratio than those according to Comparative Examples 5 to 8.

While example embodiments have been disclosed herein, it should be understood that other variations may be possible. Such variations are not to be regarded as a departure from the spirit and scope of example embodiments of the present application, and all such modifications as would be appreciated by one skilled in the art are intended to be included within the scope of the following claims.

What is claimed is:

1. A method of forming an organic thin film comprising:
providing an organic solution including an organic solute and a solvent, the solvent having a boiling point of about 85° C. or less;
dipping a substrate into the organic solution;
removing the substrate from the organic solution at a speed of about 10 to about 300 μm/s; and
precipitating the organic solute on the substrate to form the organic thin film.

2. The method of forming an organic thin film of claim 1, wherein the solvent has a boiling point ranging from about 35 to about 85° C.

3. The method of forming an organic thin film of claim 1, wherein the solvent includes acetone, methylethylketone, chloroform, dichloromethane, tetrahydrofuran, acetonitrile, benzene, cyclohexane, dichloroethane, ethanol, ethyl acetate, petroleum ether, or a combination thereof.

4. The method of forming an organic thin film of claim 1, wherein the removing the substrate from the organic solution is performed at a constant speed.

5. The method of forming an organic thin film of claim 1, wherein the removing the substrate from the organic solution is performed at a speed ranging from about 10 to about 150 μm/s.

6. The method of forming an organic thin film of claim 1, wherein the organic solute includes anthracene, tetracene, pentacene, merocyanine, copper phthalocyanine, perylene, rubrene, anthradithiophene, polyfluorene, polyacetylene, polydiacetylene, polythiophene, oligothiophene, polyisothinanaphthene, polyarylenevinylene, polyaniline, polycarbozole, polyfuran, polyacene, or derivatives thereof.

7. The method of forming an organic thin film of claim 1, wherein the organic thin film includes a plurality of crystals aligned in stripes.

8. The method of forming an organic thin film of claim 1, wherein the organic thin film has a carrier mobility of about 0.1 cm²/Vs or more.

9. The method of forming an organic thin film of claim 1, wherein the organic thin film has a carrier mobility of about 0.5 cm²/Vs or more.

10. The method of forming an organic thin film of claim 1, wherein the organic solute is included in the organic solution at a concentration of about 0.1 to about 2 wt %.

11. The method of forming an organic thin film of claim 1, wherein the organic thin film has a thickness of about 10 nm to about 5 μm.

12. An organic thin film comprising:
a plurality of crystals aligned in stripes, the organic thin film having a carrier mobility of about 0.5 cm²/Vs or more.

13. The organic thin film of claim 12, wherein the organic thin film has a thickness of about 10 nm to about 5 μm.

14. The organic thin film of claim 12, wherein the organic thin film includes anthracene, tetracene, pentacene, merocyanine, copper phthalocyanine, perylene, rubrene, anthradithiophene, polyfluorene, polyacetylene, polydiacetylene, polythiophene, oligothiophene, polyisothianaphthene, polyarylenevinylene, polyaniline, polycarbazole, polyfuran, polyacene, or derivatives thereof.

15. The organic thin film of claim 12, wherein the organic thin film is formed by:
providing an organic solution including an organic solute and a solvent, the solvent having a boiling point of about 85° C. or less;
dipping a substrate into the organic solution;
removing the substrate from the organic solution at a speed of about 10 to about 300 μm/s; and
precipitating the organic solute on the substrate to form the organic thin film.

16. A thin film transistor comprising:
a gate electrode;
a semiconductor overlapping the gate electrode;
a gate dielectric layer disposed between the gate electrode and the semiconductor; and
a source electrode and a drain electrode electrically connected to the semiconductor,
wherein the semiconductor includes the organic thin film of claim 12.

17. An electronic device comprising the thin film transistor of claim 16.

18. The method of claim 1, wherein the speed of removing the substrate is constant from a time period when the substrate initially emerges from the organic solution to when the substrate is completely removed from the organic solution.
